(19) United States
(12) Patent Application Publication
(10) Pub. No.: US 2017/0345920 A1
(43) Pub. Date: Nov. 30, 2017

(54) FIELD-EFFECT TRANSISTOR

(71) Applicant: SHARP KABUSHIKI KAISHA, Sakai City, Osaka (JP)

(72) Inventors: Tetsuzo NAGAHISA, Sakai City, Osaka (JP); Masayuki FUKUMI, Sakai City, Osaka (JP); Shinichi HANDA, Sakai City, Osaka (JP)

(73) Assignee: SHARP KABUSHIKI KAISHA, Sakai City, Osaka (JP)

(21) Appl. No.: 15/535,789

(22) PCT Filed: Aug. 21, 2015
(86) PCT No.: PCT/JP2015/073597

§ 371 Date: Jun. 14, 2017

(30) Foreign Application Priority Data
Dec. 15, 2014 (JP) 2014-252913

(51) Int. Cl. H01L 29/778; H01L 29/20; H01L 29/41; H01L 29/06; H01L 29/51

(52) U.S. Cl. CPC H01L 29/778; H01L 29/41; H01L 29/06; H01L 29/2003; H01L 29/518

(57) ABSTRACT

A field-effect transistor includes: a nitride semiconductor layer that includes a heterojunction; a source electrode and a drain electrode; a first gate electrode that is disposed to surround the drain electrode in a plan view and performs a normally-on operation; and a second gate electrode is disposed to surround the first gate electrode in a plan view and performs a normally-off operation. The first gate electrode and the second gate electrode include straight portions in which both an edge of the first gate electrode and an edge of the second gate electrode are substantially straight in the plan view and end portions formed by corner portions which are curved or bent in the plan view. An interval, a length, or a radius of curvature of one of the first gate electrode, the second gate electrode, and the source electrode is set such that concentration of an electric field at the end portion is alleviated.

### TECHNICAL FIELD

The present invention relates to a field-effect transistor that has a heterostructure field-effect transistor (HFET) structure of a nitride semiconductor.

### BACKGROUND ART

A nitride semiconductor device that has the HFET structure is generally configured to perform a normally-on (an ON state at a gate voltage of 0 V) operation at a practical use level. However, even in a case in which control of the gate voltage becomes abnormal, a normally-off (an OFF state at a gate voltage of 0 V) operation is considerably desired to perform a safety operation so that no current flows.

Incidentally, a gate withstand pressure is lowered to tens of V even when the normally-off operation can be realized. In a power device field, while a gate withstand pressure of hundreds of V or more is necessary, it is considerably difficult to realize a sufficient gate withstand pressure.

Accordingly, as in a method of realizing cascode connection using a nitride semiconductor element of the normally-on operation and a metal-oxide semiconductor (MOS) element of the normally-off operation or semiconductor devices disclosed in Japanese Unexamined Patent Application Publication No. 2010-147387 (PTL 1), Japanese Unexamined Patent Application Publication No. 2014-123665 (PTL 2), and Japanese Unexamined Patent Application Publication No. 2013-106018 (PTL 3), a method of configuring cascode connection with a simplex nitride semiconductor and a wiring using a gate of a normally-on operation of a high withstand pressure and a gate of a normally-off operation of a low withstand pressure and realizing the normally-off operation has been proposed.

For example, the semiconductor device disclosed in PTL 1 includes: a semiconductor region; a source electrode and a drain electrode which is formed on a main surface of the semiconductor region; a gate electrode of a low withstand pressure which is formed with a p-type material film installed on the main surface of the semiconductor region interposed therebetween and which indicates normally-off characteristics and is disposed between the source electrode and the drain electrode; and a fourth electrode of a high withstand pressure which is formed on the main surface of the semiconductor region and is disposed between the gate electrode and the drain electrode. When a voltage of 0 V to a voltage of tens of V is applied to the fourth electrode using the source electrode as a standard, a high voltage of 100 V is applied between the drain electrode and the fourth electrode and no high voltage is applied to the gate electrode at the time of the normally-off operation.

The semiconductor device disclosed in PTL 2 includes: a first transistor which has a first gate electrode, a first source electrode, a first drain electrode, and a first nitride semiconductor laminate structure (including a first electron transit layer and a first electron supply layer); and a second transistor which includes a p-type impurity diffusion prevention layer, a second gate electrode, a second source electrode, a second drain electrode which is a common electrode to the first source electrode, and a second nitride semiconductor laminate structure (which is a layer including a second electron supply layer and a second electron transit layer containing p-type impurities) which is formed below the second gate electrode. The second nitride semiconductor laminate structure is formed on the first nitride semiconductor laminate structure with the p-type impurity diffusion prevention layer interposed therebetween. The first gate electrode and the second source electrode are electrically connected to each other and the first transistor and the second transistor are cascode-connected. In this way, the normally-off operation is realized while reducing ON resistance and enabling a high withstand pressure.

The semiconductor device disclosed in PTL 3 includes a semiconductor laminate that includes a first heterojunction surface and a second heterojunction surface located above the first heterojunction surface; a drain electrode which is electrically connected to a first 2-dimensional electron gas layer formed on the first heterojunction surface; a source electrode which is electrically connected to a second 2-dimensional electron gas layer formed on the one second heterojunction surface electrically insulated from the first 2-dimensional electron gas layer; a gate unit which is electrically connected both the first and second 2-dimensional electron gas layers by a conductive electrode; and an auxiliary gate unit which is formed between the conductive electrode and the drain electrode on a main surface of the semiconductor laminate. The concentration of electrons of the first 2-dimensional electron gas layer is denser than the concentration of the electrons of the second 2-dimensional electron gas layer. In this way, a normally-off operation is performed, and a high withstand pressure and low ON resistance are realized.

Incidentally, in a method of configuring the cascode connection using a nitride semiconductor element of the normally-on operation and an MOS structure element of the normally-off operation, a necessary chip area is immense, and thus there is a problem with a mounting surface. Further, there is also a problem that cost is high since two types of semiconductors are handled.

In methods of configuring cascode connection with a simplex nitride semiconductor and a wiring using a gate of a normally-on operation of a high withstand pressure and a gate of a normally-off operation of a low withstand pressure and realizing the normally-off operation, as in the semiconductor devices disclosed in PTL 1 to PTL 3, two gates, that is, the gate performing the normally-off operation and the gate performing the normally-on operation, are used, and thus current leakage or breakdown occurs due to interaction between the two gates, and the source electrode and the drain electrode.

Accordingly, surrounding a drain electrode with a gate performing a normally-on operation and a gate performing a normally-off operation has been proposed.

For example, a III-nitride power semiconductor element disclosed in U.S. Pat. No. 8,174,051 (B2) (PTL 4) has a structure in which a drain electrode is surrounded by a Schottky electrode considered to be a gate performing a normally-on operation and the Schottky electrode (gate) is surrounded by a gate electrode (here, the width is narrower than the width of the Schottky electrode) considered to perform a normally-off operation.

### CITATION LIST

### Patent Literature

PTL 1: Japanese Unexamined Patent Application Publication No. 2010-147387

PTL 2: Japanese Unexamined Patent Application Publication No. 2014-123665

PTL 3: Japanese Unexamined Patent Application Publication No. 2013-106018

PTL 4: U.S. Pat. No. 8,174,051 (B2)

### SUMMARY OF INVENTION

### Technical Problem

However, in the III-nitride power semiconductor element of the related art disclosed in PTL 4, there are problems that a portion which is an end portion exists in a plan view, the concentration of an electric field in the portion is unavoidable, and current leakage or breakdown in the end portion is considerable.

Accordingly, an object of the invention is to provide a field-effect transistor in which current leakage occurring in an end portion is reduced and breakdown rarely occurs in the end portion in a case in which cascode connection is configured with a simplex nitride semiconductor and a wiring.

### Solution to Problem

To resolve the foregoing problem, according to the invention, there is provided a field-effect transistor including: a nitride semiconductor layer that includes a heterojunction; a source electrode and a drain electrode that are disposed on the nitride semiconductor layer at an interval; a first gate electrode that is located between the source electrode and the drain electrode, is disposed to surround the drain electrode in a plan view, and performs a normally-on operation; and a second gate electrode that is located between the first gate electrode and the source electrode, is disposed to surround the first gate electrode in a plan view, and performs a normally-off operation. The first gate electrode and the second gate electrode include straight portions in which both an edge of the first gate electrode and an edge of the second gate electrode are substantially straight in the plan view and end portions formed by corner portions in which an edge of the first gate electrode and an edge of the second gate electrode are curved or bent in the plan view. An interval, a length, or a radius of curvature of one of the first gate electrode, the second gate electrode, and the source electrode is set such that concentration of an electric field at the end portion is alleviated.

In the field-effect transistor according to an embodiment, an interval between the first gate electrode and the second gate electrode at the end portions may be set to be longer than an interval between the first gate electrode and the second gate electrode at the straight portions.

In the field-effect transistor according to an embodiment, an interval between the first gate electrode and the drain electrode at the end portions may be set to be longer than an interval between the first gate electrode and the drain electrode at the straight portions.

In the field-effect transistor according to an embodiment, the source electrode is disposed to surround the second gate electrode in the plan view. An interval between the second gate electrode and the source electrode at the end portions may be set to be longer than an interval of the second gate electrode and the source electrode at the straight portions.

In the field-effect transistor according to an embodiment, a length of the second gate electrode at the straight portion in a gate width direction may be set to be longer than a length of the first gate electrode at the straight portion in the gate width direction.

In the field-effect transistor according to an embodiment, one of the edge of the first gate electrode and the edge of the second gate electrode at the end portion may be arced. A minimum value of the radius of curvature of the second gate electrode at the end portion is set to be greater than a minimum value of the radius of curvature of the first gate electrode at the end portion.

### Advantageous Effects of Invention

As apparent from the above description, in the field-effect transistor according to the invention, in the plan view, the first gate electrode performing the normally-on operation is disposed to completely surround the drain electrode irrespective of the straight portion and the end portion and the second gate electrode performing the normally-off operation is disposed to completely surround the first gate electrode irrespective of the straight portion and the end portion. Accordingly, in a case in which cascode connection is configured with the simplex nitride semiconductor layer and a wiring, the end portions can be depleted at the OFF time and carriers can be prevented from moving, and thus current leakage transferring through the end portions can be reduced.

Further, the interval, the length, or the radius of curvature of one of the first gate electrode, the second gate electrode, and the source electrode is set such that concentration of an electric field at the end portion is alleviated. Accordingly, it is possible to alleviate the electric field at the end portion, and thus realize a reduction in further current leakage and an improvement in a withstand pressure.

### BRIEF DESCRIPTION OF DRAWINGS

FIG. 1 is a plan view illustrating a field-effect transistor of the invention according to a first embodiment.

FIG. 2 is a perspective sectional view taken along the line A-A′ of FIG. 1.

FIG. 3 is a plan view according to a modification example of FIG. 1.

FIG. 4 is a plan view according to a second embodiment.

FIG. 5 is a plan view according to a modification example of FIG. 4.

FIG. 6 is a plan view according to a third embodiment.

FIG. 7 is a plan view according to a fourth embodiment.

FIG. 8 is a plan view according to a modification example of FIG. 7.

FIG. 9 is a plan view according to a fifth embodiment.

FIG. 10 is a plan view according to a modification example of FIG. 9.

FIG. 11 is a plan view according to a sixth embodiment.

FIG. 12 is a plan view according to a modification example of FIG. 11.

FIG. 13 is a plan view according to a seventh embodiment.

FIG. 14 is a plan view according to a modification example of FIG. 13.

FIG. 15 is a plan view according to an eighth embodiment.

FIG. 16 is a perspective sectional view taken along the line D-D′ of FIG. 15.

FIG. 17 is a plan view according to a ninth embodiment.

FIG. 18 is a perspective sectional view taken along the line E-E′ of FIG. 17.

FIG. 19 is a view according to a tenth embodiment.

### DESCRIPTION OF EMBODIMENTS

Hereinafter, the invention will be described in detail according to embodiments to be illustrated.

### First Embodiment

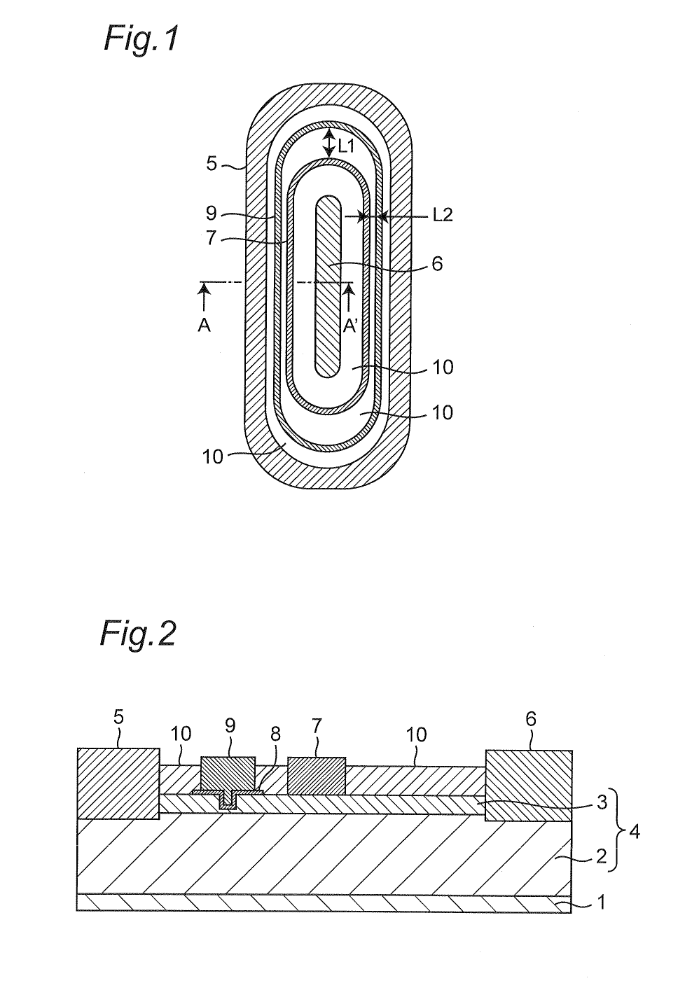

FIG. 1 is a plan view illustrating a nitride semiconductor HFET which is a field-effect transistor according to a first embodiment. FIG. 2 is a perspective sectional view taken along the line A-A′ of FIG. 1.

In the nitride semiconductor HFET, as illustrate in FIG. 2, a channel layer 2 formed of GaN and a barrier layer 3 formed of AlₓGa₁₋ₓN (where 0<x<1) are formed in this order on a substrate 1 formed of Si. Here, Al mixed crystal ratio x of AlₓGa₁₋ₓN is, for example, x=0.17. Two-dimensional electron gas (2DEG) occurs on an interface between the channel layer 2 and the barrier layer 3. In the embodiment, a nitride semiconductor 4 is configured to include the channel layer 2 and the barrier layer 3. In the embodiment, the thickness of the barrier layer 3 is, for example, 30 nm.

A source electrode 5 and a drain electrode 6 are formed on the barrier layer 3 at a preset interval. In the embodiment, Ti/Al in which Ti and Al are laminated in this order is used as the source electrode 5 and the drain electrode 6. By forming recesses in spots in which the source electrode 5 and the drain electrode 6 are formed, depositing the electrode materials, and performing annealing, ohmic contacts are formed between the source electrode 5 and the 2DEG and between the drain electrode 6 and the 2DEG.

A first gate electrode 7 performing a normally-on (ON at a gate voltage of 0 V) operation is formed on the barrier layer 3 and between the source electrode 5 and the drain electrode 6. In the embodiment, the first gate electrode 7 forms Schottky junction with the barrier layer 3 using Ni/Au in which Ni and Au are laminated in this order.

A recess of the barrier layer 3 is formed on the barrier layer 3 and between the first gate electrode 7 and the source electrode 5, a gate insulation film 8 formed of a SiO₂ film is formed between the bottom surface and the side surface of the recess and on the barrier layer 3, and a second gate electrode 9 is formed on the gate insulation film 8. The second gate electrode 9 is formed to perform a normally-off (OFF at a gate voltage of 0 V) operation.

The structure in which the recess is formed in the second gate electrode 9 and the gate insulation film 8 is formed to realize the normally-off operation as in the embodiment is merely an example. Any structure may be used as long as the structure is a structure performing the normally-off operation. For example, SiO₂ is used as the gate insulation film 8, but any material may be allowed as long as the material has an insulation property, such as SiN or Al₂O₃. For example, a structure realizing the normally-off operation by forming a p-type semiconductor on the barrier layer 3 and raising a potential below the second gate electrode 9 may also be allowed.

An insulation film 10 formed of SiN is formed on the barrier layer 3 between the source electrode 5 and the second gate electrode 9, between the second gate electrode 9 and the first gate electrode 7, and between the first gate electrode 7 and the drain electrode 6. A function of the insulation film 10 is to suppress collapse (which is a phenomenon in which ON resistance is larger than in application of a voltage in a case in which an ON state is entered after application of the voltage to a drain at an OFF time) of the nitride semiconductor 4 while insulating electrodes from each other.

SiN used for the insulation film 10 is merely an example. Any material can be used as long as the material can electrically insulate electrodes from each other, as in SiO₂, Al₂O₃, and AlN.

Here, the gist of the embodiment will be described.

In the embodiment, a cascode connection structure is configured by forming the first gate electrode 7 performing the normally-on operation and the second gate electrode 9 performing the normally-off operation on the nitride semiconductor 4 and electrically connecting the first gate electrode 7 performing the normally-on operation to the source electrode 5 by a wiring (not illustrated). The second gate electrode 9 performing the normally-off operation using the nitride semiconductor 4 generally has a low withstand pressure. However, by configuring the cascode connection in this way, the field-effect transistor with a high withstand pressure can be configured by one chip and it is possible to reduce chip cost and reduce a package size.

As illustrated in FIG. 1, both the edge of the first gate electrode 7 and the edge of the second gate electrode 9 are straight portions which are substantially straight and end portions formed by corner portions which are curved or bent in a plan view. That is, there are necessarily the end portions in the plan view.

In recent years, for the HFET, it is desirable to enable a large current to flow at the time of an ON operation other than a high withstand pressure. In a case in which a large current flows, it is general to widen a gate width. As a scheme, the above-described straight portion may be enlarged. Incidentally, due to a restriction on a region, a scheme of disposing the plurality of structures illustrated in FIG. 1 in parallel is used in conjunction with the enlarging of the straight portions.

Incidentally, the inventors have clarified that when the plurality of structures illustrated in FIG. 1 are disposed in parallel, the numbers of end portions of the first gate electrodes 7 and second gate electrodes 9 included in one chip are increased, and thus the many end portions cause an increase in current leakage and a withstand pressure failure.

As a method of preventing a withstand pressure failure and leakages transferring through the end portions, a method of causing the spots to enter an inactive state is considered. That is, at the above-described end portions, leakage is prevented by etching the barrier layer 3 and working up the inactive state in which the 2DEG does not occur. There is also a method of not applying an electric field by not forming an electrode structure in a spot which is an inactive state. However, even when the inactive state is realized in the nitride semiconductor 4, the surface of the nitride semiconductor 4 becomes a leakage source and unnegligible leakage occurs although the leakage is minuter than in an active region. Ultimately, it is considerably difficult to form a completely inactive spot. Therefore, the leakage may consequently occur between the electrodes in this method, which is not desirable.

Accordingly, according to the embodiment, as illustrated in FIG. 1, in a plan view, the drain electrode 6 is completely surrounded by the first gate electrode 7 irrespective of the straight portions and the end portions and the first gate electrode 7 is completely surrounded by the second gate electrode 9 irrespective of the straight portions and the end portions. Further, the second gate electrode 9 is surrounded by the source electrode 5 irrespective of the straight portions and the end portions. A distance L1 between the end portions of the first gate electrode 7 performing the normally-on operation and the second gate electrode 9 performing the normally-off operation is set to be longer than a distance L2 between the straight portions.

At the end portion, an electric field is easily concentrated due to the shape of the end portion, current leakage increases more easily than at the straight portion. The end portion is also a spot which is easily broken down. The second gate electrode 9 which is a normally-off electrode generally has a lower withstand pressure than the first gate electrode 7 which is a normally-on electrode. To alleviate the electric field, it is important to have a sufficient distance between both the gate electrodes 7 and 9.

In the embodiment, when the first gate electrode 7 completely surrounds the drain electrode 6 and the second gate electrode 9 further completely surrounds the first gate electrode 7 in the plan view, the end portions can also be depleted at the OFF time and carriers can be prevented from moving, and thus current leakage transferring through the end portions is reduced. Further, the distance between the first gate electrode 7 and the second gate electrode 9 at the end portions is set to be longer than the distance at the straight portions, and thus a sufficient distance can be ensured. In this way, by alleviating the electric field at the end portions, it is possible to realize a reduction in new current leakage and an improvement in a withstand pressure.

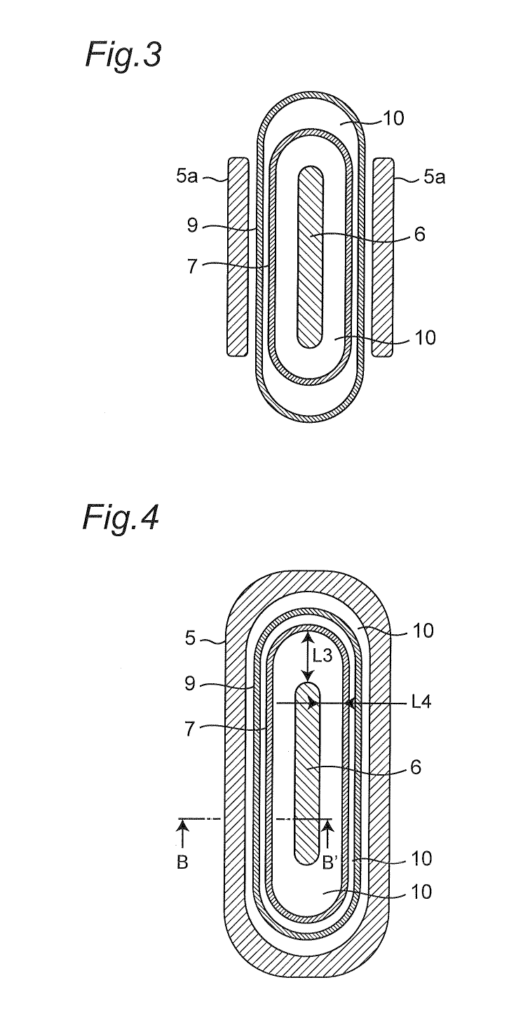

In FIG. 1, the structure in which the second gate electrode 9 is surrounded by the source electrode 5 is illustrated. However, it is not necessary to particularly surround the second gate electrode 9 in the invention. For example, as illustrated in FIG. 3, source electrodes 5a which have only straight portions may be used. In this way, concentration of a current flowing from the source electrode 5a to a narrow region which is an end portion of the drain electrode 6 can be alleviated. Consequently, it is possible to improve a short circuit capacity.

As illustrated in FIGS. 1 and 3, it is desirable that a change in the distance between the first gate electrode 7 and the second gate electrode 9 at the end portions from the straight portion sides to the forefronts of the end portions be a continuous change. In this way, since a singular point such as a concave portion disappears, the concentration of the electric field rarely occurs, thereby realizing the structure in which breakdown rarely occurs.

### Second Embodiment

FIG. 4 is a plan view illustrating a nitride semiconductor HFET which is a field-effect transistor according to a second embodiment.

In the nitride semiconductor HFET, a perspective cross-sectional surface taken along the like B-B′ in FIG. 4 has substantially the same structure as that in FIG. 2 according to the first embodiment. Accordingly, the same reference numerals are given to the same members as those of the first embodiment and the detailed description thereof will be omitted. Hereinafter, differences from the first embodiment will be described.

In the embodiment, as illustrated in FIG. 4, in a plan view, the first gate electrode 7 completely surrounds the drain electrode 6 irrespective of the straight portions and the end portions and the second gate electrode 9 completely surrounds the first gate electrode 7 irrespective of the straight portions and the end portions. Further, the source electrode 5 completely surrounds the second gate electrode 9 irrespective of the straight portions and the end portions. A distance L3 between the end portions of the first gate electrode 7 performing the normally-on operation and the drain electrode 6 is set to be longer than a distance L4 between the straight portions.

At the end portion, an electric field is easily concentrated due to the shape of the end portion, current leakage increases more easily than at the straight portion. The end portion is also a spot which is easily broken down. Since a high voltage is applied between the drain electrode 6 and the first gate electrode 7, a high withstand pressure is necessary.

Accordingly, in the embodiment, when the first gate electrode 7 completely surrounds the drain electrode 6 and the second gate electrode 9 further completely surrounds the first gate electrode 7 in the plan view, the end portions can also be depleted at the OFF time and carriers can be prevented from moving, and thus current leakage transferring through the end portions is reduced. Further, the distance between the first gate electrode 7 and the drain electrode 6 at the end portions is set to be longer than the distance at the straight portions, and thus a sufficient distance can be ensured. In this way, by alleviating the electric field at the end portions, it is possible to realize a reduction in new current leakage and an improvement in a withstand pressure.

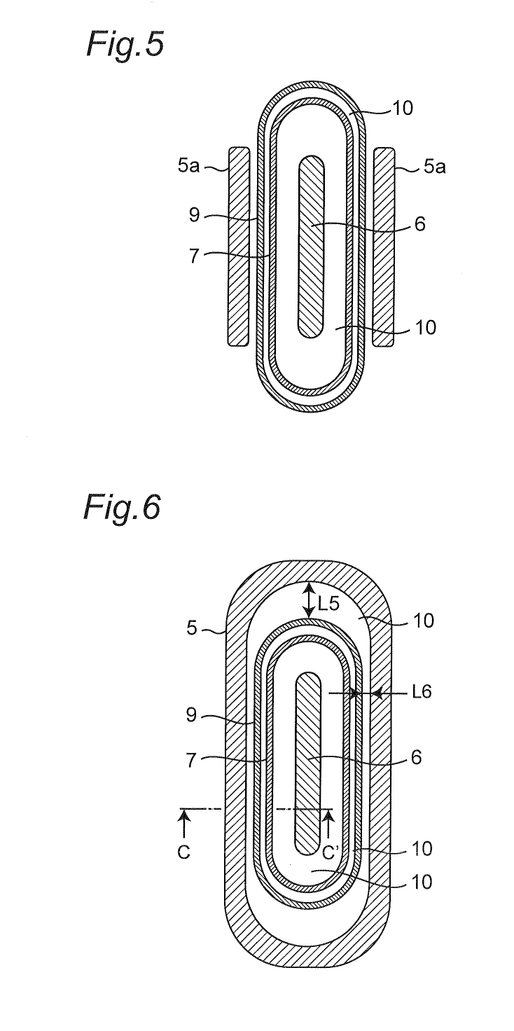

In FIG. 4, the structure in which the second gate electrode 9 is surrounded by the source electrode 5 is illustrated. However, it is not necessary to particularly surround the second gate electrode 9 in the invention. For example, as illustrated in FIG. 5, source electrodes 5a which have only straight portions may be used. In this way, concentration of a current flowing from the source electrode 5a to a narrow region which is an end portion of the drain electrode 6 can be alleviated. Consequently, it is possible to improve a short circuit capacity.

As illustrated in FIGS. 4 and 5, it is desirable that a change in the distance between the first gate electrode 7 and the drain electrode 6 from the straight portions to the forefronts of the end portions be a continuous change. In this way, since a singular point such as a concave portion disappears, the concentration of the electric field rarely occurs, thereby realizing the structure in which breakdown rarely occurs.

### Third Embodiment

FIG. 6 is a plan view illustrating a nitride semiconductor HFET which is a field-effect transistor according to a third embodiment.

In the nitride semiconductor HFET, a perspective cross-sectional surface taken along the like C-C′ in FIG. 6 has substantially the same structure as that in FIG. 2 according to the first embodiment. Accordingly, the same reference numerals are given to the same members as those of the first embodiment and the detailed description thereof will be omitted. Hereinafter, differences from the first and second embodiments will be described.

In the embodiment, as illustrated in FIG. 6, in a plan view, the first gate electrode 7 completely surrounds the drain electrode 6 irrespective of the straight portions and the end portions and the second gate electrode 9 completely surrounds the first gate electrode 7 irrespective of the straight portions and the end portions. Further, the source electrode 5 completely surrounds the second gate electrode 9 irrespective of the straight portions and the end portions. A distance L5 between the end portions of the second gate electrode 9 performing the normally-off operation and the source electrode 5 is set to be longer than a distance L6 between the straight portions.

At the end portion, an electric field is easily concentrated due to the shape of the end portion, current leakage increases more easily than at the straight portion. The end portion is also a spot which is easily broken down. Since the second gate electrode 9 performing the normally-off operation generally has a low withstand pressure, a structure in which the electric field is alleviated is necessary at the end portion on which an electric field is concentrated.

Accordingly, in the embodiment, when the first gate electrode 7 completely surrounds the drain electrode 6 and the second gate electrode 9 further completely surrounds the first gate electrode 7 in the plan view, the end portions can also be depleted at the OFF time and carriers can be prevented from moving, and thus current leakage transferring through the end portions is reduced. Further, the distance between the second gate electrode 9 and the source electrode 5 at the end portions is set to be longer than the distance at the straight portions, and thus a sufficient distance can be ensured. In this way, by alleviating the electric field at the end portions, it is possible to realize a reduction in new current leakage and an improvement in a withstand pressure.

As illustrated in FIG. 6, it is desirable that a change in the distance between the second gate electrode 9 and the source electrode 5 from the straight portion sides to the forefronts of the end portions be a continuous change. In this way, since a singular point such as a concave portion disappears, the concentration of the electric field rarely occurs, thereby realizing the structure in which breakdown rarely occurs.

### Fourth Embodiment

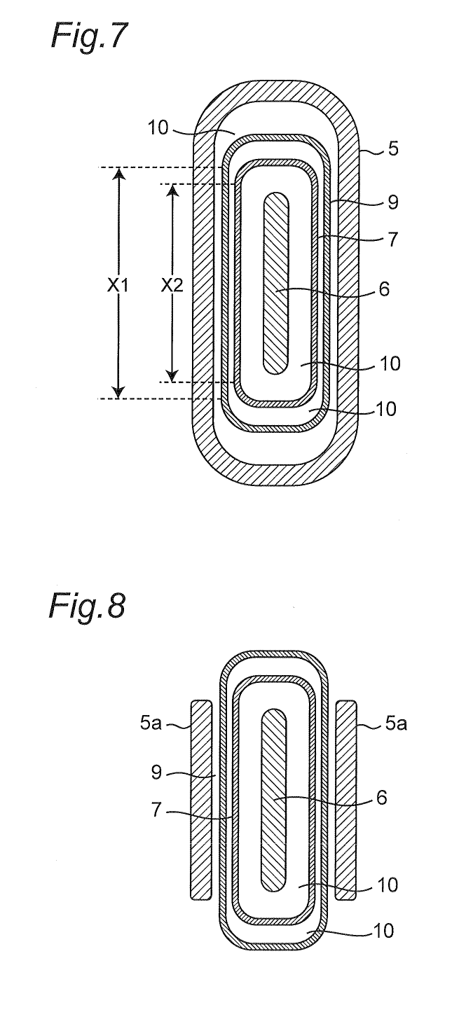

FIG. 7 is a plan view illustrating a nitride semiconductor HFET which is a field-effect transistor according to a fourth embodiment.

In the nitride semiconductor HFET, a cross-sectional surface in a direction orthogonal to the extension direction of the drain electrode 6 in FIG. 7 has substantially the same structure as that in FIG. 2 according to the first embodiment. Accordingly, the same reference numerals are given to the same members as those of the first embodiment and the detailed description thereof will be omitted. Hereinafter, differences from the first to third embodiments will be described.

In the embodiment, as illustrated in FIG. 7, in a plan view, the first gate electrode 7 completely surrounds the drain electrode 6 irrespective of the straight portions and the end portions and the second gate electrode 9 completely surrounds the first gate electrode 7 irrespective of the straight portions and the end portions. Further, the source electrode 5 completely surrounds the second gate electrode 9 irrespective of the straight portions and the end portions. A length X1 of the straight portions of the second gate electrode 9 performing the normally-off operation in the gate width direction is set to be longer than a length X2 of the straight portions of the first gate electrode 7 performing the normally-on operation in the gate width direction.

At the end portion, an electric field is easily concentrated at the bent corner portion due to the shape of the end portion in a plan view, current leakage increases more easily than at the straight portion. The end portion is also a spot which is easily broken down.

Accordingly, in the embodiment, when the first gate electrode 7 completely surrounds the drain electrode 6 and the second gate electrode 9 further completely surrounds the first gate electrode 7 in the plan view, the end portions can also be depleted at the OFF time and carriers can be prevented from moving, and thus current leakage transferring through the end portions is reduced. Further, a structure designed to realize a reduction in the leakage and an improvement in a withstand pressure is realized by ensuring the straight portions of the outside gate electrode in the plan view to be longer and forming a portion in which an electric field strength is strong at the end portion of the inside gate electrode in a region facing the straight portion rather than the end portion in which there is the bent corner portion of the outside gate electrode Here, the reason for forming the region facing the straight portion of the outside gate electrode is that the bent corner portion of the end portion of the inside gate electrode is a portion in which the current leakage and the withstand pressure easily deteriorate since the extension direction of the electrode is not constant in crystal orientation of the nitride semiconductor 4. Further, the reason is that the outside gate electrode facing the portion on which an electric field is easily concentrated, such as the end portion of the inside gate electrode, is a straight portion as much as possible. Accordingly, it is possible to realize a reduction in new current leakage and an improvement in a withstand pressure.

In FIG. 7, the structure in which the second gate electrode 9 is surrounded by the source electrode 5 is illustrated. However, it is not necessary to particularly surround the second gate electrode 9 in the invention. For example, as illustrated in FIG. 8, source electrodes 5a which have only straight portions may be used. In this way, concentration of a current flowing from the source electrode 5a to a narrow region which is an end portion of the drain electrode 6 can be alleviated. Consequently, it is possible to improve a short circuit capacity.

### Fifth Embodiment

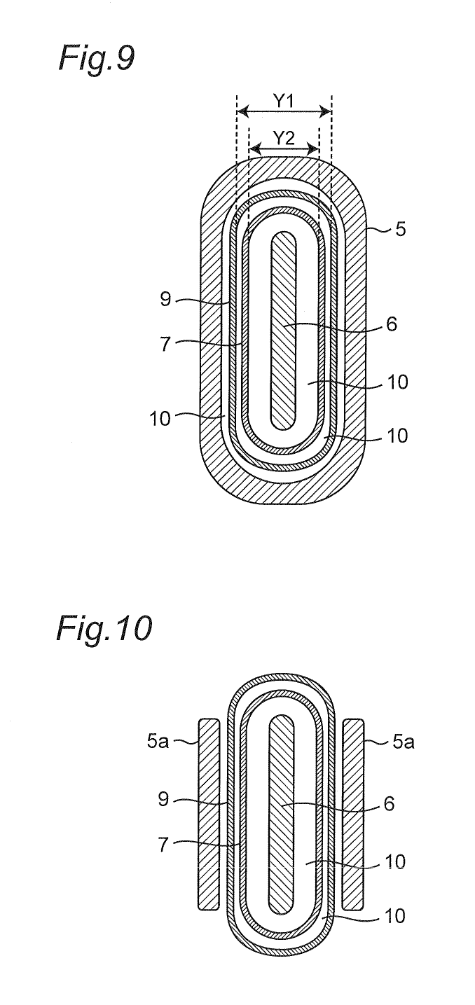

FIG. 9 is a plan view illustrating a nitride semiconductor HFET which is a field-effect transistor according to a fifth embodiment.

In the nitride semiconductor HFET, a cross-sectional surface in a direction orthogonal to the extension direction of the drain electrode 6 in FIG. 9 has substantially the same structure as that in FIG. 2 according to the first embodiment. Accordingly, the same reference numerals are given to the same members as those of the first embodiment and the detailed description thereof will be omitted. Hereinafter, differences from the first to fourth embodiments will be described.

In the embodiment, as illustrated in FIG. 9, in a plan view, the first gate electrode 7 completely surrounds the drain electrode 6 irrespective of the straight portions and the end portions and the second gate electrode 9 completely surrounds the first gate electrode 7 irrespective of the straight portions and the end portions. Further, the source electrode 5 completely surrounds the second gate electrode 9 irrespective of the straight portions and the end portions. The end portions of the second gate electrode 9 performing the normally-off operation and the end portions of the first gate electrode 7 performing the normally-on operation are arced. A minimum value of the radius of curvature of the end portions of the second gate electrode 9 is set to be greater than a minimum value of the radius of curvature of the end portion of the first gate electrode 7.

As the length of the end portion in a direction orthogonal to the extension direction of the drain electrode 6 (Y1 in the second gate electrode 9 and Y2 in the first gate electrode 7) is longer, an electric field is easily concentrated even in the same radius of curvature. Consequently, the current leakage easily increases and the end portion is a spot which is easily broken down.

Accordingly, in the embodiment, when the first gate electrode 7 completely surrounds the drain electrode 6 and the second gate electrode 9 further completely surrounds the first gate electrode 7 in the plan view, the end portions can also be depleted at the OFF time and carriers can be prevented from moving, and thus current leakage transferring through the end portions is reduced. Further, as the length of the end portion in the direction orthogonal to the extension direction of the drain electrode 6 is longer, it is necessary to sufficiently enlarge the radius of curvature. Therefore, the minimum value of the radius of curvature of the end portions of the second gate electrode 9 is set to be greater than the minimum value of the radius of curvature of the end portion of the first gate electrode 7. Accordingly, it is possible to realize a reduction in new current leakage and an improvement in a withstand pressure.

Here, in a case in which the shape of the arc is, for example, semi-ellipsoidal, the radius of curvature differs depending on a location. Therefore, to express a spot indicating a small value of the radius of curvature in the end portion, that is, the portion with a most projected shape, a “minimum value” of the radius of curvature will be mentioned.

The shapes of the first gate electrode 7 and the second gate electrode 9 at the end portions are “arced”, as described above, but may be, of course, semicircular. In a case in which the shapes are semicircular, the radius of curvature is constant. Therefore, “the minimum value of the radius of curvature” may also be substituted with “the radius of curvature”.

In FIG. 9, a structure in which the second gate electrode 9 is surrounded by the source electrode 5 is illustrated. However, it is not necessary to particularly surround the second gate electrode 9 in the invention. For example, as illustrated in FIG. 10, source electrodes 5a which have only straight portions may be used. In this way, concentration of a current flowing from the source electrode 5a to a narrow region which is an end portion of the drain electrode 6 can be alleviated. Consequently, it is possible to improve a short circuit capacity.

As illustrated in FIGS. 9 and 10, it is desirable that a change in the radius of curvature at the end portions of the second gate electrode 9 and the first gate electrode 7 that are arced be a continuous change. In this way, since a singular point such as a concave portion disappears, the concentration of the electric field rarely occurs, thereby realizing the structure in which breakdown rarely occurs.

### Sixth Embodiment

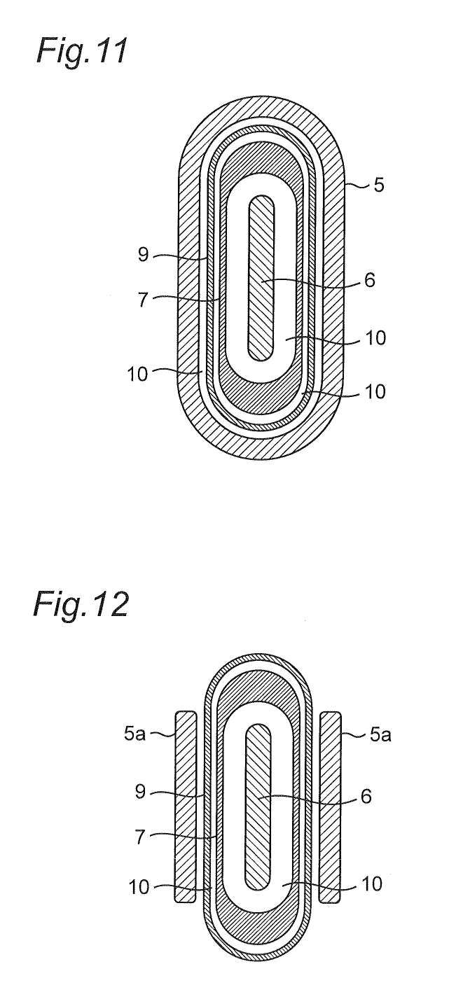

FIG. 11 is a plan view illustrating a nitride semiconductor HFET which is a field-effect transistor according to a sixth embodiment.

In the nitride semiconductor HFET, a cross-sectional surface in a direction orthogonal to the extension direction of the drain electrode 6 in FIG. 11 has substantially the same structure as that in FIG. 2 according to the first embodiment. Accordingly, the same reference numerals are given to the same members as those of the first embodiment and the detailed description thereof will be omitted. Hereinafter, differences from the first to fifth embodiments will be described.

In the embodiment, as illustrated in FIG. 11, in a plan view, the first gate electrode 7 completely surrounds the drain electrode 6 irrespective of the straight portions and the end portions and the second gate electrode 9 completely surrounds the first gate electrode 7 irrespective of the straight portions and the end portions. Further, the source electrode 5 completely surrounds the second gate electrode 9 irrespective of the straight portions and the end portions. A gate length of the first gate electrode 7 performing the normally-on operation at the end portion is set to be longer than a gate length at the straight portion.

At the end portion, an electric field is easily concentrated due to the shape of the end portion and a short channel effect easily occurs. When the short channel effect occurs, sub-threshold leakage flowing between the source electrode 5 and the drain electrode 6 may occur.

Accordingly, in the embodiment, when the first gate electrode 7 completely surrounds the drain electrode 6 and the second gate electrode 9 further completely surrounds the first gate electrode 7 in the plan view, the end portions can also be depleted at the OFF time and carriers can be prevented from moving, and thus current leakage transferring through the end portions is reduced. Further, the gate length of the first gate electrode 7 at the end portion is sufficiently longer than the gate length at the straight portion. In this way, it is possible to prevent the short channel effect and realize a reduction in new current leakage and an improvement in a withstand pressure.

In FIG. 11, the structure in which the second gate electrode 9 is surrounded by the source electrode 5 is illustrated. However, it is not necessary to particularly surround the second gate electrode 9 in the invention. For example, as illustrated in FIG. 12, source electrodes 5a which have only straight portions may be used. In this way, concentration of a current flowing from the source electrode 5a to a narrow region which is an end portion of the drain electrode 6 can be alleviated. Consequently, it is possible to improve a short circuit capacity.

As illustrated in FIGS. 11 and 12, it is desirable that a change in the gate length of the first gate electrode 7 at the end portion from the straight portion side to the apex of the end portion be a continuous change. In this way, since a singular point such as a concave portion disappears, the concentration of the electric field rarely occurs, thereby realizing the structure in which breakdown rarely occurs.

### Seventh Embodiment

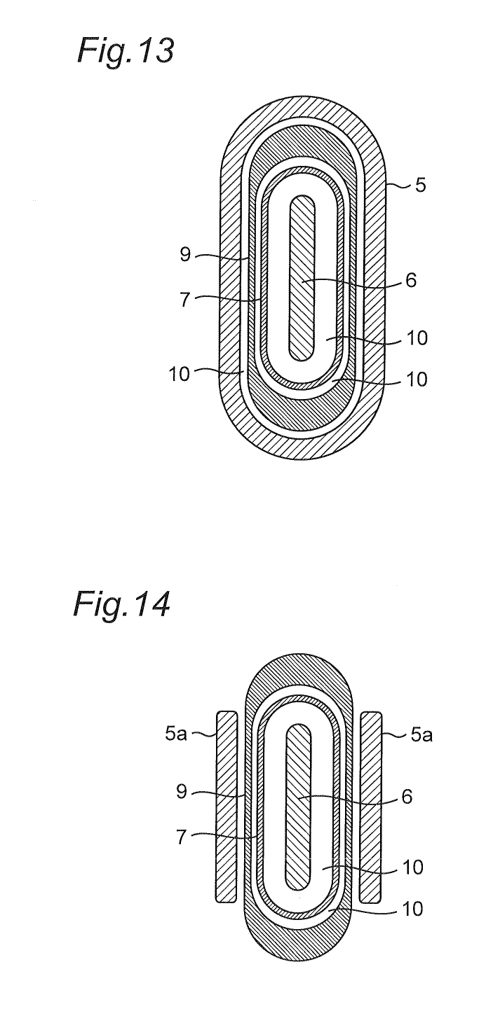

FIG. 13 is a plan view illustrating a nitride semiconductor HFET which is a field-effect transistor according to a seventh embodiment.

In the nitride semiconductor HFET, a cross-sectional surface in a direction orthogonal to the extension direction of the drain electrode 6 in FIG. 13 has substantially the same structure as that in FIG. 2 according to the first embodiment. Accordingly, the same reference numerals are given to the same members as those of the first embodiment and the detailed description thereof will be omitted. Hereinafter, differences from the first to sixth embodiments will be described.

In the embodiment, as illustrated in FIG. 13, in a plan view, the first gate electrode 7 completely surrounds the drain electrode 6 irrespective of the straight portions and the end portions and the second gate electrode 9 completely surrounds the first gate electrode 7 irrespective of the straight portions and the end portions. Further, the source electrode 5 completely surrounds the second gate electrode 9 irrespective of the straight portions and the end portions. A gate length of the second gate electrode 9 performing the normally-off operation at the end portion is set to be longer than a gate length at the straight portion.

At the end portion, an electric field is easily concentrated due to the shape of the end portion and a short channel effect easily occurs. When the short channel effect occurs, sub-threshold leakage flowing between the source electrode 5 and the drain electrode 6 may occur.

Accordingly, in the embodiment, when the first gate electrode 7 completely surrounds the drain electrode 6 and the second gate electrode 9 further completely surrounds the first gate electrode 7 in the plan view, the end portions can also be depleted at the OFF time and carriers can be prevented from moving, and thus current leakage transferring through the end portions is reduced. Further, the gate length of the second gate electrode 9 at the end portion is sufficiently longer than the gate length at the straight portion. In this way, it is possible to prevent the short channel effect and realize a reduction in new current leakage and an improvement in a withstand pressure.

In FIG. 13, the structure in which the second gate electrode 9 is surrounded by the source electrode 5 is illustrated. However, it is not necessary to particularly surround the second gate electrode 9 in the invention. For example, as illustrated in FIG. 14, source electrodes 5a which have only straight portions may be used. In this way, concentration of a current flowing from the source electrode 5a to a narrow region which is an end portion of the drain electrode 6 can be alleviated. Consequently, it is possible to improve a short circuit capacity.

As illustrated in FIGS. 13 and 14, it is desirable that a change in the gate length of the second gate electrode 9 at the end portion from the straight portion side to the apex of the end portion be a continuous change. In this way, since a singular point such as a concave portion disappears, the concentration of the electric field rarely occurs, thereby realizing the structure in which breakdown rarely occurs.

### Eighth Embodiment

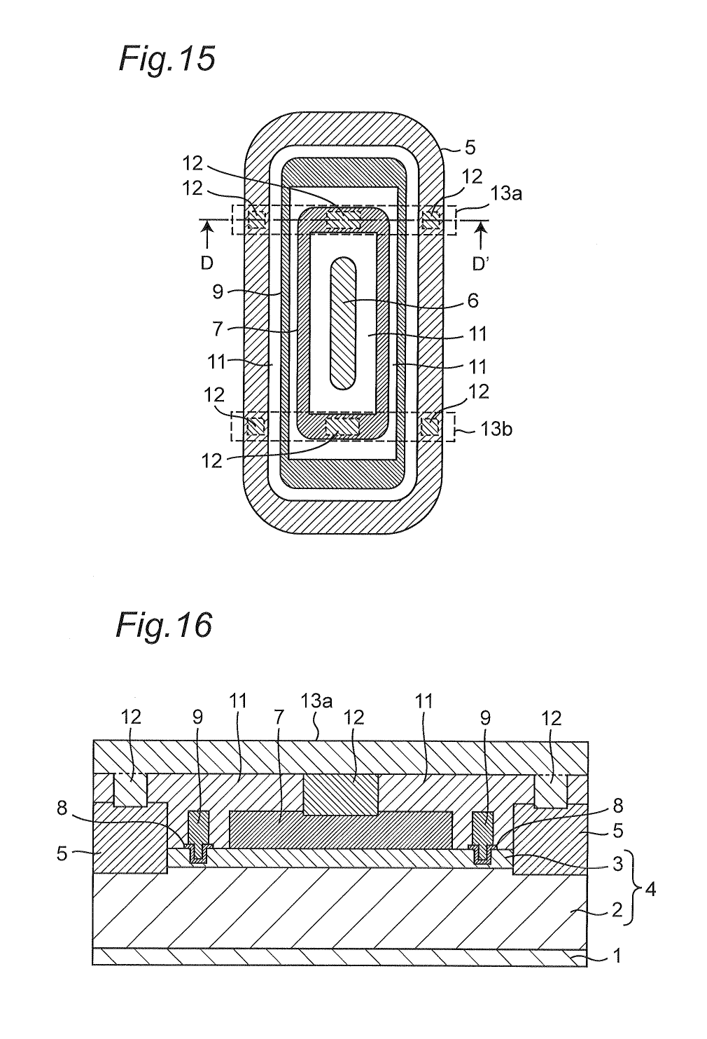

FIG. 15 is a plan view illustrating a nitride semiconductor HFET which is a field-effect transistor according to an eighth embodiment. FIG. 16 is a perspective sectional view taken along the line D-D′ of FIG. 15.

The substrate 1, the channel layer 2, the barrier layer 3, the nitride semiconductor 4, the source electrode 5, the drain electrode 6, the first gate electrode 7, the gate insulation film 8, and the second gate electrode 9 in the nitride semiconductor HFET have substantially the same structures of a case of the nitride semiconductor HFET according to the first embodiment. Accordingly, the same reference numerals are given to the same members as those of the first embodiment and the detailed description thereof will be omitted. Hereinafter, differences from the first to seventh embodiments will be described.

According to the eighth embodiment, an insulation film 11 formed of SiN is formed throughout all of the barrier layer 3, the source electrode 5, the drain electrode 6, the first gate electrode 7, and the second gate electrode 9. Accordingly, the insulation film 11 is also formed on the barrier layer 3 between the source electrode 5 and the second gate electrode 9, between the second gate electrode 9 and the first gate electrode 7, and between the first gate electrode 7 and the drain electrode 6.

As illustrated in FIGS. 15 ad 16, at both the end portions of the first gate electrode 7, contact holes 12 are formed on the source electrode 5 and the first gate electrode 7 in the insulation film 11. Two conductive layers 13a and 13b are formed on the insulation film 11 from the contact hole 12 of the source electrode 5 to the contact hole 12 of the source electrode 5 on the opposite side through the contact hole 12 of the first gate electrode 7. In this way, the source electrode 5 and the first gate electrode 7 are electrically connected to each other via the contact holes 12 by the conductive layers 13a and 13b.

In this way, it is possible to considerably reduce parasitic inductance when the cascode connection is realized, and thus it is possible to perform a stability operation.

### Ninth Embodiment

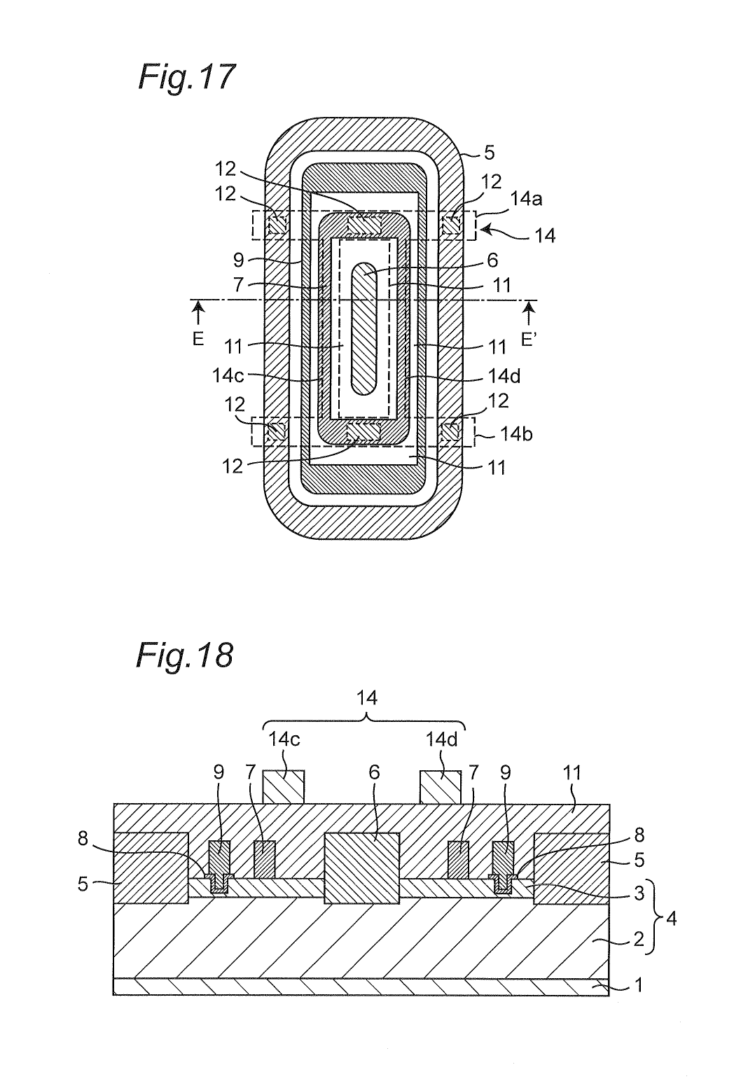

FIG. 17 is a plan view illustrating a nitride semiconductor HFET which is a field-effect transistor according to a ninth embodiment. FIG. 18 is a perspective sectional view taken along the line E-E′ of FIG. 17.

The substrate 1, the channel layer 2, the barrier layer 3, the nitride semiconductor 4, the source electrode 5, the drain electrode 6, the first gate electrode 7, the gate insulation film 8, and the second gate electrode 9 in the nitride semiconductor HFET have substantially the same structures of a case of the nitride semiconductor HFET according to the first embodiment. Accordingly, the same reference numerals are given to the same members as those of the first embodiment and the detailed description thereof will be omitted.

Further, the insulation film 11 and the contact holes 12 have substantially the same structures as the case of the nitride semiconductor HFET in the eighth embodiment. Accordingly, the same reference numerals are given to the same members as those of the eighth embodiment and the detailed description thereof will be omitted.

Hereinafter, differences from the first to eighth embodiments will be described.

According to the ninth embodiment, as illustrated in FIGS. 17 and 18, at both the end portions of the first gate electrode 7, two conductive layers 14a and 14b are formed on the insulation film 11 from the contact hole 12 of the source electrode 5 to the contact hole 12 of the source electrode 5 on the opposite side through the contact hole 12 of the first gate electrode 7. Further, two conductive layers 14c and 14d of which end portions are connected to the two conductive layers 14a and 14b and which are disposed between the two conductive layers 14a and 14b are formed. In this case, the conductive layers 14c and 14d are disposed on the two straight portions of the first gate electrode 7 and extend in an eave shape from the upper side of the first gate electrode 7 toward the side of the drain electrode 6.

In this way, the source electrode 5 and the first gate electrode 7 are electrically connected via the contact holes 12 by the conductive layer portion 14 in which the four conductive layers 14a, 14b, 14c, and 14d are combined with the shape of the Roman number “II”.

That is, according to the embodiment, at the straight portions, the conductive layer portions 14 do not exist on the second gate electrode 9. Therefore, it is possible to reduce parasitic capacitance between the source and the gate. In addition, it is possible to alleviate the concentration of an electric field on the first gate electrode 7 by the conductive layers 14c and 14d formed in the eave shape and it is possible to suppress the collapse and improve the withstand pressure.

### Tenth Embodiment

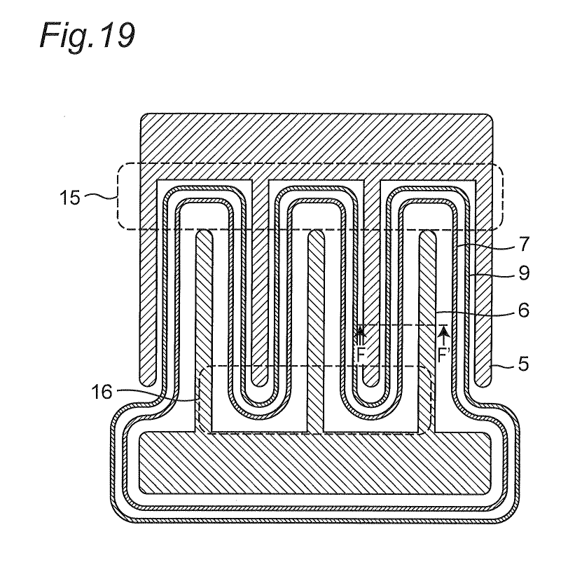

FIG. 19 is a plan view illustrating a nitride semiconductor HFET which is a field-effect transistor according to a tenth embodiment. Here, a perspective cross-sectional surface taken along the like F-F′ in FIG. 19 has substantially the same structure as that in FIG. 2 according to the first embodiment.

The embodiment is a modification example of the first to ninth embodiments. The first to seventh embodiments are applied to a case in which the source electrode 5 and the drain electrode 6 have a shape of so-called comb-shaped electrode. That is, a structure in which the drain electrode 6 is surrounded by the first gate electrode 7 and the first gate electrode 7 is surrounded by the second gate electrode 9 is realized. In this case, reference numerals 15 and 16 denote the end portions.

FIG. 19 illustrates a basic structure in a case in which the first to seventh embodiments are applied. In practice, the structure is realized as follows.

In a case in which the first embodiment is applied, a distance between the first gate electrode 7 and the second gate electrode 9 at the end portion 15 is set to be longer than a distance at the straight portion.

In a case in which the second embodiment is applied, a distance between the first gate electrode 7 and the drain electrode 6 at the end portion 15 is set to be longer than a distance at the straight portion.

In a case in which the third embodiment is applied, a distance between the second gate electrode 9 and the source electrode 5 at the end portion 15 is set to be longer than a distance at the straight portion.

In a case in which the fourth embodiment is applied, the length of the second gate electrode 9 in the gate width direction at the straight portion is set to be longer than that of the first gate electrode 7.

In a case in which the fifth embodiment is applied, the minimum value of the radius of curvature of the second gate electrode 9 at the end portion 15 is set to be greater than that of the first gate electrode 7.

In a case in which the sixth embodiment is applied, the gate length of the first gate electrode 7 at the end portion 15 is set to be longer than at the straight portion.

In a case in which the seventh embodiment is applied, the gate length of the second gate electrode 9 at the end portion 15 is set to be longer than at the straight portion.

Even in a case in which the source electrode 5 and the drain electrode 6 have the shape of a comb-shaped electrode, a field-effect transistor (nitride semiconductor HFET) in which leakage is reduced can be realized in the foregoing configuration.

In each of the embodiments, a Si substrate is used as the substrate 1 of the nitride semiconductor HFET. However, a sapphire substrate, a SiC substrate, or a GaN substrate may be used without being limited to the Si substrate.

Further, GaN is used as the channel layer 2 and AlₓGa₁₋ₓN is used as the barrier layer 3. However, the channel layer 2 and the barrier layer 3 are not limited to GaN and AlₓGa₁₋ₓN, but the nitride semiconductor 4 expressed with AlₓInyGa_{1-x-y}N (where x≧0, y≧0, and 0≦x+y<1) may be included. That is, the nitride semiconductor 4 may contain AlGaN, GaN, and InGaN or the like.

Further, a buffer layer may be appropriately formed in the nitride semiconductor 4 used in the invention. An AlN layer with a layer thickness of about 1 nm may be formed between the channel layer 2 and the barrier layer 3 in order to improve mobility. GaN may be formed as a cap layer on the barrier layer 3.

In each of the embodiments, by forming recesses in spots in which the source electrode 5 and the drain electrode 6 in the barrier layer 3 and the channel layer 2 are formed, depositing the electrode materials in the recesses, and performing annealing, the ohmic contacts are formed between the source electrode 5 and the drain electrode 6, and the 2DEG. However, the method of forming the ohmic contacts is not limited thereto. For example, any forming method may be performed as long as the ohmic contacts can be formed between the electrodes 5 and 6, and the 2DEG. For example, a contact undoped AlGaN layer is formed with a thickness of, for example, 15 nm on the channel layer 2. Then, the ohmic contacts may be formed by directly depositing an electrode material on the undoped AlGaN layer without forming recesses, forming the source electrode 5 and the drain electrode 6, and performing annealing.

In each of the embodiments, the first gate electrode 7 forms the Schottky junction with the barrier layer 3 using Ni/Au in which Ni and Au are laminated in this order. However, the invention is not limited thereto and any material may be used as long as the gate electrode can function as a gate of a transistor. For example, a metal such as W, Ti, Ni, Al, Pd, Pt, or Au, a nitride such as WN or TiN, an alloy thereof, and a laminate structure thereof can be used. The first gate electrode 7 is not limited to be used to form the Schottky junction with the nitride semiconductor 4. A gate insulation film may be formed between the first gate electrode 7 and the nitride semiconductor 4.

In each of the embodiments, the source electrode 5 and the drain electrode 6 are formed using Ti/Al in which Ti and Al are laminated in this order. However, the invention is not limited thereto. Any material may be used as long as the material has an electrical conduction property and ohmic contact with the 2DEG is possible. For example, Ti/Al/TiN in which Ti, Al, and TiN are laminated in this order may be used. In addition, AlSi, AlCu, and Au may be used instead of the foregoing Al or may be laminated on the foregoing Al.

The dimensions of the portions and the film thicknesses in the embodiment are merely examples and are within an application range of the invention in the structure according to the invention.

In summary, the field-effect transistor according to the invention includes: the nitride semiconductor layer 4 that includes a heterojunction; the source electrode 5 and the drain electrode 6 that are disposed on the nitride semiconductor layer 4 at an interval; the first gate electrode 7 that is located between the source electrode 5 and the drain electrode 6, is disposed to surround the drain electrode 6 in a plan view, and perform a normally-on operation; and the second gate electrode 9 that is located between the first gate electrode 7 and the source electrode 5, is disposed to surround the first gate electrode 7 in a plan view, and performs a normally-off operation. The first gate electrode 7 and the second gate electrode 9 include straight portions in which both an edge of the first gate electrode 7 and an edge of the second gate electrode 9 are substantially straight in the plan view and end portions in which an edge of the first gate electrode 7 and an edge of the second gate electrode 9 are curved or bent corner portions in the plan view. The interval, the length, or the radius of curvature of one of the first gate electrode 7, the second gate electrode 9, and the source electrode 5 is set such that concentration of an electric field at the end portion is alleviated.

In the configuration, in the plan view, the first gate electrode 7 performing the normally-on operation is disposed to completely surround the drain electrode 6 irrespective of the straight portion and the end portion and the second gate electrode 9 performing the normally-off operation is disposed to completely surround the first gate electrode 7 irrespective of the straight portion and the end portion. Accordingly, the end portions can be depleted at the OFF time and carriers can be prevented from moving, and thus current leakage transferring through the end portions can be reduced.

Further, the interval, the length, or the radius of curvature of one of the first gate electrode 7, the second gate electrode 9, and the source electrode 5 is set such that concentration of an electric field at the end portion is alleviated. Accordingly, it is possible to alleviate the electric field at the end portion, and thus realize the reduction in the new current leakage and the improvement in the withstand pressure.

According to an embodiment, in the field-effect transistor, an interval between the first gate electrode 7 and the second gate electrode 9 at the end portions is set to be longer than an interval between the first gate electrode 7 and the second gate electrode 9 at the straight portions.

At the end portion, an electric field is easily concentrated due to the shape of the end portion, current leakage increases more easily than at the straight portion. The end portions are spots which are easily broken down. The second gate electrode 9 which is a normally-off electrode generally has a lower withstand pressure than the first gate electrode 7 which is a normally-on electrode.

According to the embodiment, the interval between the first gate electrode 7 and the second gate electrode 9 at the end portions is set to be longer than an interval between the first gate electrode 7 and the second gate electrode 9 at the straight portions. Accordingly, it is possible to alleviate the electric field at the end portion, and thus realize the reduction in the new current leakage and the improvement in the withstand pressure (in particular, a withstand pressure of the second gate electrode 9).

According to an embodiment, in the field-effect transistor, an interval between the first gate electrode 7 and the drain electrode 6 at the end portions is set to be longer than an interval between the first gate electrode 7 and the drain electrode 6 at the straight portions.

According to the embodiment, the interval between the first gate electrode 7 and the drain electrode 6 at the end portions is set to be longer than an interval between the first gate electrode 7 and the drain electrode 6 at the straight portions. Accordingly, it is possible to alleviate the electric field at the end portion, and thus realize the reduction in the new current leakage and the improvement in the withstand pressure.

According to an embodiment, in the field-effect transistor, the source electrode 5 is disposed to surround the second gate electrode 9 in the plan view. An interval between the second gate electrode 9 and the source electrode 5 at the end portions is set to be longer than an interval of the second gate electrode 9 and the source electrode 5 at the straight portions.

According to the embodiment, the interval between the second gate electrode 9 and the source electrode 5 at the end portions is set to be longer than the interval of the second gate electrode 9 and the source electrode 5 at the straight portions. Accordingly, it is possible to alleviate the electric field at the end portion, and thus realize the reduction in the new current leakage and the improvement in the withstand pressure.

According to an embodiment, in the field-effect transistor, the length of the second gate electrode 9 at the straight portion in a gate width direction is set to be longer than a length of the first gate electrode 7 at the straight portion in the gate width direction.

The end portion is a spot in which an electric field is easily concentrated due to the shape of the end portion current leakage increases more easily than in the straight portion and which is easily broken down.

According to the embodiment, the length of the second gate electrode 9 at the straight portion in a gate width direction is set to be longer than a length of the first gate electrode 7 at the straight portion in the gate width direction. Accordingly, a structure designed to realize a reduction in the leakage and an improvement in a withstand pressure is realized by enlarging the straight portions of the second gate electrode 9 located outside and forming a portion in which an electric field strength is strong at the end portion of the inside gate electrode in a region facing the straight portion rather than the end portion in which there is the bent corner portion of the outside gate electrode. Here, the reason for forming the region facing the straight portion of the outside gate electrode is that the bent corner portion of the end portion of the inside gate electrode is a portion in which the current leakage and the withstand pressure easily deteriorate since the extension direction of the electrode is not constant in crystal orientation of the nitride semiconductor 4. Further, the reason is that the outside gate electrode facing the portion in which an electric field is concentrated easily, such as the end portion of the inside gate electrode, is a straight portion as much as possible. Accordingly, it is possible to realize the reduction in the new current leakage and the improvement in the withstand pressure.

According to an embodiment, in the field-effect transistor, one of the edge of the first gate electrode 7 and the edge of the second gate electrode 9 at the end portion is arced. A minimum value of the radius of curvature of the second gate electrode 9 at the end portion is set to be greater than a minimum value of the radius of curvature of the first gate electrode 7 at the end portion.

According to the embodiment, the minimum value of the radius of curvature of the second gate electrode 9 which is arced at the end portion is set to be greater than the minimum value of the radius of curvature of the first gate electrode 7 which is arched at the end portion. Accordingly, the minimum value of the radius of curvature of the second gate electrode 9 which has a longer length in the direction orthogonal to the extension direction of the drain electrode 6 at the end portion can be set to be greater than the minimum value of the radius of curvature of the first gate electrode 7 which has a shorter length in the gate width direction, and thus it is possible to realize the reduction in the new current leakage and the improvement in the withstand pressure.

According to an embodiment, in the field-effect transistor, the gate length of the first gate electrode 7 at the end portion is set to be longer than the gate length of the first gate electrode 7 at the straight portion.

At the end portion, an electric field is easily concentrated due to the shape of the end portion and a short channel effect easily occurs. When the short channel effect occurs, sub-threshold leakage flowing between the source electrode 5 and the drain electrode 6 may occur.

According to the embodiment, the gate length of the first gate electrode 7 at the end portion is set to be longer than the gate length of the first gate electrode 7 at the straight portion. Accordingly, it is possible to prevent the short channel effect and realize the reduction in the new current leakage and the improvement in the withstand pressure.

According to an embodiment, in the field-effect transistor, the gate length of the second gate electrode 9 at the end portion is set to be longer than the gate length of the second gate electrode 9 at the straight portion.

At the end portion, an electric field is easily concentrated due to the shape of the end portion and a short channel effect easily occurs. When the short channel effect occurs, sub-threshold leakage flowing between the source electrode 5 and the drain electrode 6 may occur.

According to the embodiment, the gate length of the second gate electrode 9 at the end portion is set to be longer than the gate length of the second gate electrode 9 at the straight portion. Accordingly, it is possible to prevent the short channel effect and realize the reduction in the new current leakage and the improvement in the withstand pressure.

According to an embodiment, in the field-effect transistor, in regard to the straight portion side to the apex at the end portion, a change in the interval between the respective electrodes, a change in the radius of curvature of each gate electrode, or a change in the gate length of each gate electrode is a continuous change.

According to the embodiment, the change in the interval between the electrodes, the change in the radius of curvature of each gate electrode, and the change in the gate length of each gate electrode are continuous changes. Accordingly, since a singular point such as a concave portion disappears, the concentration of the electric field rarely occurs, thereby realizing the structure in which breakdown rarely occurs.

According to an embodiment, the field-effect transistor includes: the insulation film 11 that is formed throughout the source electrode 5, the drain electrode 6, the first gate electrode 7, and the second gate electrode 9; the contact holes 12 that are formed on the source electrode 5 and the first gate electrode 7 in the insulation film 11; and the conductive layers 13a, 13b, 14a, and 14b that are formed from the spot of the source electrode 5 to the spot of the first gate electrode 7 on the insulation film 11 and electrically connect the source electrode 5 to the first gate electrode 7 via the contact hole 12.

According to the embodiment, the source electrode 5 and the first gate electrode 7 are electrically connected to each other via the contact holes 12 by the conductive layers 13a, 13b, 14a, and 14b formed on the insulation film 11. Accordingly, it is possible to considerably reduce parasitic inductance when the cascode connection is realized, and thus it is possible to perform a stability operation.

According to an embodiment, in the field-effect transistor, the conductive layers 14a and 14b serve as first conductive layers, and the contact hole 12 formed on the first gate electrode 7 and the first conductive layers 14a and 14b are located at the end portions of the first gate electrode 7. The field-effect transistor includes the second conductive layers 14c and 14d which are formed on the insulation film 11 to overlap the straight portions of the first gate electrodes 7 in a plan view and of which one end is connected to the first conductive layer 14a located at one of the end portions of the first gate electrode 7, and the other is connected to the first conductive layer 14b located at the other of the end portions of the first gate electrode 7. The second conductive layers 14c and 14d. include the extension portions that extend in an eave shape from the upper side of the first gate electrode 7 toward the side of the drain electrode 6.

According to the embodiment, at the straight portions, the first conductive layers 14a and 14b and the second conductive layers 14c and 14d do not exist on the second gate electrode 9. Therefore, it is possible to reduce parasitic capacitance between the source and the gate. In addition, it is possible to alleviate the concentration of an electric field on the first gate electrode 7 by the second conductive layers 14c and 14d formed in the eave shape and it is possible to suppress the collapse and improve the withstand pressure.

### REFERENCE SIGNS LIST

1 SUBSTRATE

2 CHANNEL LAYER

3 BARRIER LAYER

4 NITRIDE SEMICONDUCTOR

5 SOURCE ELECTRODE

6 DRAIN ELECTRODE

7 FIRST GATE ELECTRODE

8 GATE INSULATION FILM

9 SECOND GATE ELECTRODE

10, 11 INSULATION FILM

12 CONTACT HOLE

13a, 13b, 14a, 14b, 14c, 14d CONDUCTIVE LAYER

14 CONDUCTIVE LAYER PORTION

15, 16 END PORTION

1-6. (canceled)

7. A field-effect transistor comprising:
a nitride semiconductor layer that includes a heterojunction;
a source electrode and a drain electrode that are disposed on the nitride semiconductor layer at an interval;
a first gate electrode that is located between the source electrode and the drain electrode, is disposed to surround the drain electrode in a plan view, and performs a normally-on operation; and
a second gate electrode that is located between the first gate electrode and the source electrode, is disposed to surround the first gate electrode in the plan view, and performs a normally-off operation,
wherein the first gate electrode and the second gate electrode each include a straight portion having a substantially straight edge and a curved end portion in the plan view, and
wherein a gate length of the first gate electrode at the curved end portion is longer than a gate length of the first gate electrode at the straight portion.

8. The field-effect transistor according to claim 7,
wherein an interval between the first gate electrode and the second gate electrode at the curved end portion is longer than an interval between the first gate electrode and the second gate electrode at the straight portion.

9. The field-effect transistor according to claim 7,
wherein an interval between the first gate electrode and the drain electrode at the curved end portion is longer than an interval between the first gate electrode and the drain electrode at the straight portion.

10. The field-effect transistor according to claim 7,
wherein the source electrode is disposed to surround the second gate electrode in the plan view, and
wherein an interval between the second gate electrode and the source electrode at the curved end portion is longer than an interval of the second gate electrode and the source electrode at the straight portion.

11. The field-effect transistor according to claim 7,
wherein a length of the second gate electrode at the straight portion in a gate width direction is longer than a length of the first gate electrode at the straight portion in the gate width direction.

12. The field-effect transistor according to claim 7,
wherein the edge of the first gate electrode and the edge of the second gate electrode at the curved end portion are arced, and
wherein a minimum value of a radius of curvature of the second gate electrode at the curved end portion is greater than a minimum value of a radius of curvature of the first gate electrode at the curved end portion.

13. A field-effect transistor comprising:
a nitride semiconductor layer that includes a heterojunction;
a source electrode and a drain electrode that are disposed on the nitride semiconductor layer at an interval;
a first gate electrode that is located between the source electrode and the drain electrode, is disposed to surround the drain electrode in a plan view, and performs a normally-on operation; and
a second gate electrode that is located between the first gate electrode and the source electrode, is disposed to surround the first gate electrode in the plan view, and performs a normally-off operation,
wherein the first gate electrode and the second gate electrode each include a straight portion having a substantially straight edge and a curved end portion in the plan view, and
wherein a gate length of the second gate electrode at the end portion is longer than a gate length of the second gate electrode at the straight portion.

14. The field-effect transistor according to claim 13,
wherein an interval between the first gate electrode and the second gate electrode at the curved end portion is longer than an interval between the first gate electrode and the second gate electrode at the straight portion.

15. The field-effect transistor according to claim 13,
wherein an interval between the first gate electrode and the drain electrode at the curved end portion is longer than an interval between the first gate electrode and the drain electrode at the straight portion.

16. The field-effect transistor according to claim 13,
wherein the source electrode is disposed to surround the second gate electrode in the plan view, and
wherein an interval between the second gate electrode and the source electrode at the curved end portion is longer than an interval of the second gate electrode and the source electrode at the straight portion.

17. The field-effect transistor according to claim 13,
wherein a length of the second gate electrode at the straight portion in a gate width direction is longer than a length of the first gate electrode at the straight portion in the gate width direction.

18. The field-effect transistor according to claim 13,
wherein the edge of the first gate electrode and the edge of the second gate electrode at the curved end portion are arced, and
wherein a minimum value of a radius of curvature of the second gate electrode at the curved end portion is greater than a minimum value of a radius of curvature of the first gate electrode at the curved end portion.
